(19) United States
(12) Patent Application Publication
(10) Pub. No.: US 2026/0282354 A1
(43) Pub. Date: Sep. 17, 2026

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Masashi SASAKI, Yokkaichi (JP)

(21) Appl. No.: 19/332,648

(22) Filed: Sep. 18, 2025

(30) Foreign Application Priority Data
Mar. 14, 2025 (JP) 2025-040809

(51) Int. Cl. H10B 43/27; H10B 43/35

(52) U.S. Cl. CPC H10B 43/27; H10B 43/35

(57) ABSTRACT

A semiconductor memory device includes: a stacked body including a plurality of first conductive layers and a plurality of insulating layers alternately stacked on top of one another in a vertical direction; a contact extending through the stacked body and reaching one of the plurality of first conductive layers; and a first pillar including a semiconductor layer that is separated from the contact and extends through the stacked body in the vertical direction. The contact includes an extension portion extending through the stacked body in the vertical direction, and an expansion portion extending from a lower end portion of the extension portion to the one first conductive layer to contact the one first conductive layer.

### CROSS-REFERENCE TO RELATED APPLICATION

This application is based upon and claims the benefit of priority from Japanese Patent Application No. 2025-040809, filed Mar. 14, 2025, the entire contents of which are incorporated herein by reference.

### FIELD

Embodiments described herein relate generally to a semiconductor memory device and a method of manufacturing a semiconductor memory device.

### BACKGROUND

A semiconductor memory device such as a three-dimensional non-volatile memory has, for example, a configuration in which memory cells are three-dimensionally arranged in a stacked body where a plurality of conductive layers are stacked. In order to electrically lead out these conductive layers, for example, contacts that reach the conductive layers, respectively, are formed. In addition, the plurality of conductive layers are formed, for example, by replacing a plurality of sacrificial layers with a conductive material.

### DESCRIPTION OF THE DRAWINGS

FIGS. 1A and 1B are diagrams illustrating a schematic configuration example of a semiconductor memory device according to an embodiment.

FIGS. 2A to 2E are diagrams illustrating an example of a configuration of the semiconductor memory device according to the embodiment.

FIG. 3 is a cross-sectional view taken along an XY plane illustrating the example of the configuration of the semiconductor memory device according to the embodiment.

FIGS. 4A to 4D are cross-sectional views sequentially illustrating a part of a procedure of a method of manufacturing the semiconductor memory device according to the embodiment.

FIGS. 5A to 5C are cross-sectional views sequentially illustrating a part of the procedure of the method of manufacturing the semiconductor memory device according to the embodiment.

FIGS. 6A to 6C are cross-sectional views sequentially illustrating a part of the procedure of the method of manufacturing the semiconductor memory device according to the embodiment.

FIGS. 7A to 7C are cross-sectional views sequentially illustrating a part of the procedure of the method of manufacturing the semiconductor memory device according to the embodiment.

FIGS. 8A to 8C are cross-sectional views sequentially illustrating a part of the procedure of the method of manufacturing the semiconductor memory device according to the embodiment.

FIGS. 9A to 9D are cross-sectional views sequentially illustrating a part of the procedure of the method of manufacturing the semiconductor memory device according to the embodiment.

FIGS. 10A to 10C are cross-sectional views sequentially illustrating a part of the procedure of the method of manufacturing the semiconductor memory device according to the embodiment.

FIGS. 11A to 11D are cross-sectional views sequentially illustrating a part of the procedure of the method of manufacturing the semiconductor memory device according to the embodiment.

FIGS. 12A to 12D are cross-sectional views illustrating a part of a procedure of a method of forming a contact according to Comparative Example.

FIGS. 13A and 13B are diagrams illustrating an example of a configuration of a semiconductor memory device according to a modification example of the embodiment.

FIGS. 14A to 14C are cross-sectional views sequentially illustrating a part of a procedure of a method of forming a contact according to the modification example of the embodiment.

FIGS. 15A to 15G are cross-sectional views sequentially illustrating a part of a procedure of a method of forming a contact according to the modification example of the embodiment.

### DETAILED DESCRIPTION

Embodiments provide a semiconductor memory device capable of preventing blocking of a conductive layer at a contact lower end portion during formation of a plurality of conductive layers, and a method of manufacturing the semiconductor memory device.

In general, according to one embodiment, a semiconductor memory device includes: a stacked body including a plurality of first conductive layers and a plurality of insulating layers alternately stacked on top of one another in a vertical direction; a contact extending through the stacked body and reaching one of the plurality of first conductive layers; and a first pillar including a semiconductor layer that is separated from the contact and extends through the stacked body in the vertical direction. The contact includes an extension portion extending through the stacked body in the vertical direction, and an expansion portion extending from a lower end portion of the extension portion to the one first conductive layer to contact the one first conductive layer.

Hereinafter, an embodiment will be described in detail with reference to the drawings. The present disclosure is not limited to the following embodiment. Elements in the following embodiments include those that can be easily conceived by those skilled in the art or those that are substantially identical.

### Configuration Example of Semiconductor Memory Device

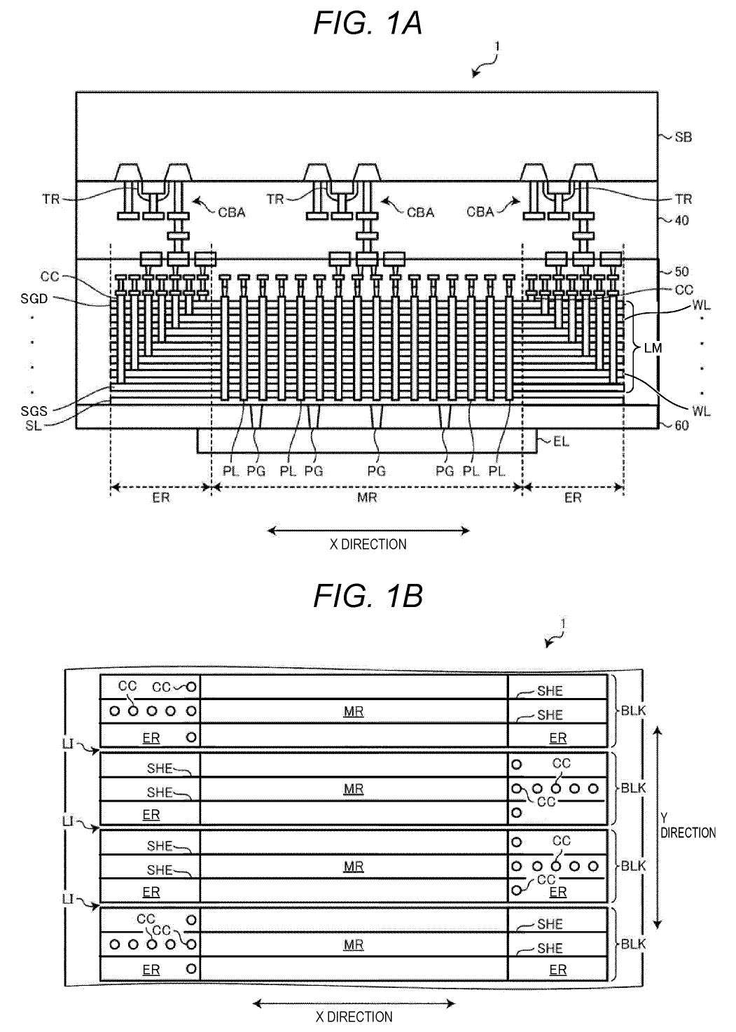

FIGS. 1A and 1B are diagrams illustrating a schematic configuration example of a semiconductor memory device 1 according to an embodiment. More specifically, FIG. 1A is a cross-sectional view illustrating the semiconductor memory device 1 taken along an X direction, and FIG. 1B is a schematic plan view illustrating a layout of the semiconductor memory device 1.

Meanwhile, hatching is omitted in FIG. 1A in consideration of clarity of the drawings. In addition, in FIG. 1A, configurations that are not necessarily present in the same cross-section are illustrated, and some upper layer wirings and the like are not illustrated.

Further, in the present specification, both the X direction and a Y direction are directions along the orientation of a surface of a word line WL, and the X direction and the Y direction are orthogonal to each other. In addition, an electrical lead-out direction of the word line WL will also be referred to as a first direction, and this first direction is a direction along the X direction. In addition, a direction intersecting the first direction will also be referred to as a second direction, and this second direction is a direction along the Y direction. Meanwhile, since the semiconductor memory device 1 may include a manufacturing error, the first direction and the second direction are not necessarily orthogonal to each other.

As illustrated in FIG. 1A, the semiconductor memory device 1 includes a semiconductor substrate SB on which an electrode film EL, a source line SL, one or more select gate lines SGS, a plurality of word lines WL, one or more select gate lines SGD, and a peripheral circuit CBA are provided in order from a lower side of the paper plane.

The source line SL is disposed on the electrode film EL with an insulating layer 60 interposed therebetween. A plurality of plugs PG are disposed in the insulating layer 60, and electrical connection between the source line SL and the electrode film EL through the plugs PG is maintained. Although not illustrated in the drawing, an electrode pad for supplying power and a signal to the semiconductor memory device 1 from the outside is provided in the same layer as the electrode film EL. On the source line SL, the select gate line SGS, the plurality of word lines WL, and the select gate line SGD are stacked in this order to configure a stacked body LM.

As illustrated in FIGS. 1A and 1B, a memory region MR is disposed in a central portion of the plurality of word lines WL in the X direction, and a contact region ER is disposed in each of both end portions of the plurality of word lines WL in the X direction. The memory region MR and the contact region ER are divided into a plurality of regions by a plurality of plate-shaped portions LI that penetrate the plurality of word lines WL and the like and extend in the direction along the X direction.

In addition, a region that is disposed between the plate-shaped portions LI adjacent to each other in the Y direction and includes the memory region MR and the contact region ER will be referred to as a block region BLK. As described below, the memory region MR includes a plurality of memory cells that store data in a non-volatile manner, and the block region BLK is a unit of data erasure.

In addition, a plurality of separation layers SHE that penetrate the select gate line SGD and extend in the direction along the X direction are disposed between the plate-shaped portions LI adjacent to each other in the Y direction. The plurality of separation layers SHE extend across the entire stacked body LM in the direction along the X direction. In one block region BLK, the select gate line SGD is separated into a plurality of regions by the separation layers SHE. In other words, the separation layers SHE penetrate portions of a layer above the plurality of word lines WL such that the upper layer portions are divided in a pattern of the plurality of select gate lines SGD.

A plurality of pillars PL that penetrate the word lines WL and the select gate lines SGD and SGS in a stacking direction are disposed in the memory region MR. A lower end of the pillar PL reaches the source line SL. A plurality of memory cells are formed in intersections between the pillars PL and the word lines WL. As a result, the semiconductor memory device 1 is configured as, for example, a three-dimensional non-volatile memory in which the memory cells are three-dimensionally arranged in the memory region MR.

In the contact region ER, a plurality of contacts CC that extend up to different depth positions in the stacked body LM and are connected to the plurality of word lines WL and the select gate lines SGD and SGS, respectively, are disposed. At this time, in one block BLK, one contact CC is connected to each of the word lines WL and the select gate line SGS. Meanwhile, in the select gate line SGD, the contact CC is connected to each of the sections separated by the separation layer SHE.

In the present specification, a direction in which the contact CC extends toward the word line WL or the like to be connected among the word lines WL or the like is defined as a lower direction in the semiconductor memory device 1.

Here, in one block region BLK, a plurality of contacts CC are disposed in one of the contact regions ER on both sides in the X direction. In addition, when seen from one side in the X direction, for example, a plurality of contacts CC are disposed for every two block regions BLK.

That is, in the example illustrated in FIG. 1B, in a block region BLK in the uppermost portion of the paper plane, a plurality of contacts CC are disposed, for example, in the contact region ER on the left side of the paper plane among the contact regions ER in both of the end portions in the X direction. In addition, in block regions BLK positioned below the above-described block region BLK by one region or two regions, respectively, a plurality of contacts CC are disposed, for example, in the contact region ER on the right side of the paper plane among the contact regions ER in both of the end portions in the X direction. Further, in a block region BLK in the lowermost portion of the paper plane, a plurality of contacts CC are disposed again in the contact region ER on the left side of the paper plane.

Therefore, the contacts CC in the contact regions ER in both of the end portions in the X direction illustrated in FIG. 1A belong to different block regions BLK, and are not actually positioned in the same cross-section.

The word lines WL and the like stacked in multiple layers are individually led out by the contacts CC. More specifically, a write voltage, a read voltage, and the like are applied from the contacts CC to the memory cells provided in the memory region MR in the central portion of the plurality of word lines WL through the word lines WL at the same height position as the memory cells.

The plurality of word lines WL, the select gate lines SGD and SGS, the pillars PL, and the contacts CC are covered with an insulating layer 50. The insulating layer 50 also spreads around these configurations.

The semiconductor substrate SB above the insulating layer 50 is, for example, a silicon substrate. The peripheral circuit CBA including a transistor TR, a wiring, and the like is disposed on a surface of the semiconductor substrate SB. Various voltages applied from the contacts CC to the memory cells are controlled by the peripheral circuit CBA electrically connected to the contacts CC. As a result, the peripheral circuit CBA controls an electrical operation of the memory cells.

The peripheral circuit CBA is covered with an insulating layer 40, and the insulating layer 40 and the insulating layer 50 covering the plurality of word lines WL and the like are joined to configure the semiconductor memory device 1 including the configurations, such as the plurality of word lines WL and select gate lines SGD and SGS, the pillars PL, and the contacts CC, and the peripheral circuit CBA.

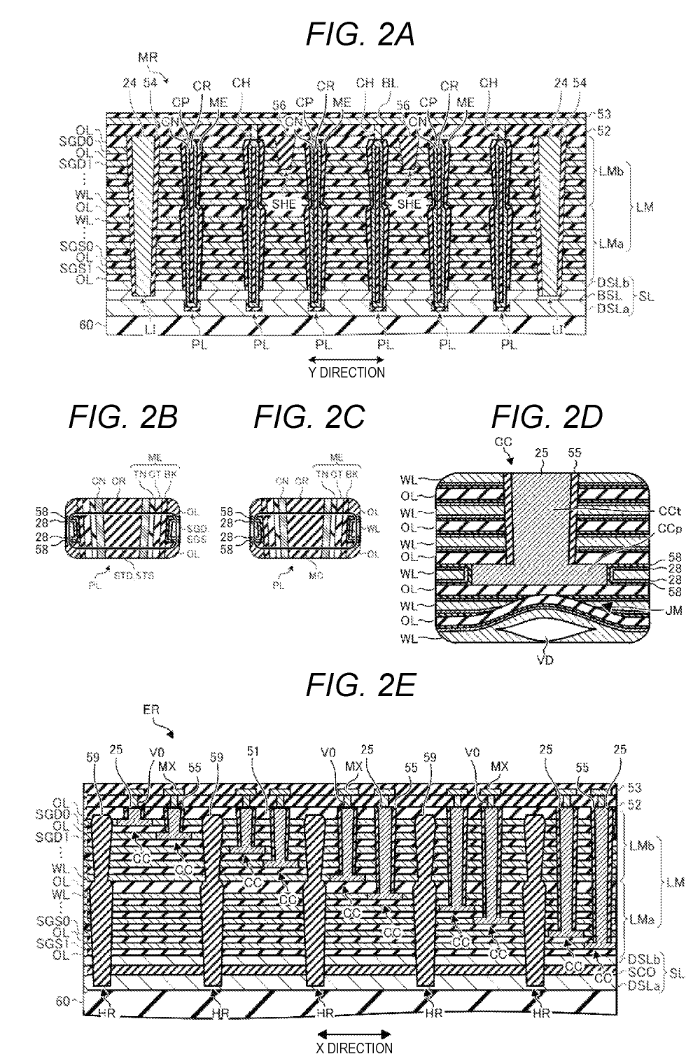

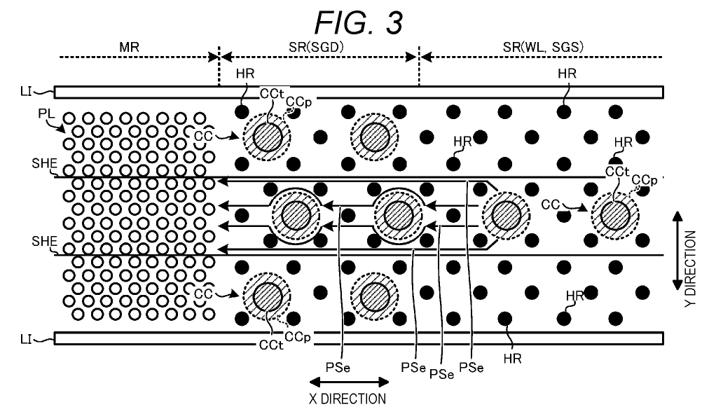

Next, the detailed configuration example of the semiconductor memory device 1 will be described using FIGS. 2A to 3.

FIGS. 2A to 2E are diagrams illustrating the example of the configuration of the semiconductor memory device 1 according to the embodiment. More specifically, FIG. 2A is a cross-sectional view taken along the Y direction illustrating the memory region MR of the semiconductor memory device 1. In FIG. 2A, a structure below the insulating layer 60 and a structure above an insulating layer 53 described below are not illustrated.

FIG. 2B is an enlarged cross-sectional view illustrating the pillar PL at the height position of the select gate lines SGD and SGS. FIG. 2C is an enlarged cross-sectional view illustrating the pillar PL at the height position of the word line WL. FIG. 2D is an enlarged cross-sectional view illustrating the contact CC at the height position of the word line WL.

FIG. 2E is a cross-sectional view taken along the X direction illustrating the contact region ER of the semiconductor memory device 1. In FIG. 2E, the structure below the insulating layer 60 and the structure above the insulating layer 53 described below are not illustrated.

As illustrated in FIG. 2A, the source line SL has a multilayer structure in which, for example, a lower source line DSLa, an intermediate source line BSL, and an upper source line DSLb are stacked in this order on the insulating layer 60. The intermediate source line BSL is disposed below the memory region MR of the stacked body LM.

The lower source line DSLa, the intermediate source line BSL, and the upper source line DSLb are, for example, polysilicon layers. Among these, at least the intermediate source line BSL may be a conductive polysilicon layer or the like in which impurities are diffused.

The source line SL is connected to the peripheral circuit CBA through the electrode film EL by a through contact (not illustrated) that extends in the insulating layer 50 outside the stacked body LM from the electrode film EL to the peripheral circuit CBA.

The stacked body LM is disposed on the source line SL. The stacked body LM includes stacked bodies LMa and LMb in which a plurality of word lines WL and a plurality of insulating layers OL are alternately stacked.

The stacked body LMa is disposed above the source line SL. In a layer below the word line WL in the lowermost layer of the stacked body LMa, a plurality of select gate lines SGS0 and SGS1 are disposed in this order from the upper layer side of the stacked body LMa with the insulating layer OL interposed therebetween. The stacked body LMb is disposed on the stacked body LMa. In a layer above the word line WL in the uppermost layer of the stacked body LMb, a plurality of select gate lines SGD0 and SGD1 are disposed in this order from the upper layer side of the stacked body LMb with the insulating layer OL interposed therebetween.

Meanwhile, the number of the word lines WL and the select gate lines SGD and SGS stacked in the stacked body LM is optional. The word line WL and the select gate lines SGD and SGS are, for example, tungsten layers or molybdenum layers. The insulating layer OL is, for example, a silicon oxide layer.

As illustrated in FIGS. 2B to 2D, a metal element-containing layer 28 and a metal element-containing layer 58 are disposed in this order on both surfaces of the plurality of word lines WL and the select gate lines SGD and SGS in the stacking direction.

When the word line WL or the like is a tungsten layer or the like, the metal element-containing layer 28 is, for example, at least any of a titanium layer, a titanium nitride layer, a tantalum layer, or a tantalum nitride layer, and functions as a barrier metal layer that prevents diffusion of tungsten atoms into a configuration in the vicinity of the word line WL. When the word line WL or the like is a molybdenum layer or the like, the metal element-containing layer 28 is, for example, a molybdenum nitride layer, and functions as a precursor for forming the word line WL or the like.

The metal element-containing layer 58 is, for example, an aluminum oxide (Al₂O₃) layer, and functions as a block insulating layer in a memory cell MC.

As illustrated in FIG. 2A, an upper surface of the stacked body LM is covered with an insulating layer 52. The insulating layer 52 is covered with the insulating layer 53. Each of the insulating layers 52 and 53 configures a portion of the insulating layer 50 of FIGS. 1A and 1B.

As described above, the stacked body LM is divided by the plurality of plate-shaped portions LI in the Y direction. That is, the plate-shaped portions LI are arranged in the Y direction, and extend in the stacking direction of the stacked body LM and the direction along the X direction.

This way, the plate-shaped portion LI continuously extends in the stacked body LM from one end portion to the other end portion of the stacked body LM in the X direction. In addition, the plate-shaped portion LI penetrates the stacked body LM and the upper source line DSLb, and reaches the intermediate source line BSL in the memory region MR.

In addition, the plate-shaped portion LI has, for example, a tapered shape in which the width in the Y direction decreases from the upper end portion toward a lower end portion. Alternatively, the plate-shaped portion LI has, for example, a bowing shape in which the width in the Y direction is the maximum at a predetermined position between the upper end portion and the lower end portion.

Each of the plate-shaped portions LI includes an insulating layer 54 and a conductive layer 24. The insulating layer 54 is, for example, a silicon oxide layer. The conductive layer 24 is, for example, a tungsten layer or a conductive polysilicon layer. The insulating layer 54 covers side walls of the plate-shaped portion LI facing each other in the Y direction. The inside of the insulating layer 54 is filled with the conductive layer 24.

Meanwhile, instead of the plate-shaped portion LI, a plate-shaped member filled with an insulating layer may penetrate the stacked body LM and extend in the direction along the X direction to divide the stacked body LM in the Y direction.

A plurality of separation layers SHE that penetrate the upper layer portion of the stacked body LMb and extend in the direction along the X direction are disposed between the plate-shaped portions LI adjacent to each other in the Y direction. The separation layers SHE are insulating layers 56, such as silicon oxide layers, that penetrate the select gate lines SGD0 and SGD1 and reach the insulating layer OL immediately below the select gate line SGD1.

In other words, the separation layers SHE penetrating the upper layer portion of the stacked body LMb extend in the X direction in the memory region MR and the contact region ER between the plate-shaped portions LI such that the upper layer portion of the stacked body LMb is divided into the select gate lines SGD0 and SGD1.

In the memory region MR, a plurality of pillars PL that penetrate the stacked body LM, the upper source line DSLb, and the intermediate source line BSL and reach the lower source line DSLa are dispersed and disposed.

Each of the pillars PL has, for example, a circular shape, an elliptical shape, or an oval shape as a cross-sectional shape in a direction along the stacking direction of the stacked body LM, that is, in a direction along the XY plane.

In addition, in the pillar PL, each of a portion that penetrates the stacked body LMa and a portion that penetrates the stacked body LMb has a tapered shape in which the diameter and the cross-sectional area decrease from the upper layer side toward the lower layer side. Alternatively, in the pillar PL, each of the portion that penetrates the stacked body LMa and the portion that penetrates the stacked body LMb has, for example, a bowing shape in which the diameter and the cross-sectional area are the maximum values at a predetermined position between the upper layer side and the lower layer side.

Each of the plurality of pillars PL includes a memory layer ME that extends in the stacking direction in the stacked body LM, a channel layer CN that penetrates the stacked body LM and is connected to the intermediate source line BSL, a cap layer CP that covers an upper surface of the channel layer CN, and a core layer CR that is a core material of the pillar PL.

As illustrated in FIGS. 2B and 2C, the memory layer ME has a multilayer structure in which a block insulating layer BK, a charge storage layer CT, and a tunnel insulating layer TN are stacked in this order from an outer peripheral side of the pillar PL. More specifically, the memory layer ME is disposed on a side surface of the pillar PL excluding a depth position of the intermediate source line BSL. In addition, the memory layer ME is also disposed on a bottom surface of the pillar PL that reaches the depth of the lower source line DSLa.

The channel layer CN penetrates the stacked body LM, the upper source line DSLb, and the intermediate source line BSL and reaches the depth of the lower source line DSLa on the inner side of the memory layer ME. More specifically, the channel layer CN is disposed on the side surface and the bottom surface of the pillar PL while the outer periphery thereof is covered with the memory layer ME. Meanwhile, a portion of the channel layer CN is in contact with the intermediate source line BSL on the side surface to be electrically connected to the source line SL including the intermediate source line BSL. A region on the inner side of the channel layer CN is filled with the core layer CR.

In addition, each of the plurality of pillars PL includes the cap layer CP in an upper end portion. The cap layer CP is disposed in the upper end portion of the pillar PL to cover at least the upper end portion of the channel layer CN, and is connected to the channel layer CN. In addition, the cap layer CP is connected to a bit line BL disposed in the insulating layer 53 through a plug CH disposed in the insulating layer 52. The bit line BL extends above the stacked body LM in the direction along the Y direction to intersect the lead-out direction of the word line WL.

In FIG. 2A, the plugs CH are connected only to three of six pillars PL that penetrate three separated select gate lines SGD, respectively, and are electrically connected to the bit line BL illustrated in FIG. 2A. The rest of the pillars PL are connected to another bit line BL through the plugs CH (not illustrated in FIG. 2A) at a position different from that in the cross-section illustrated in FIG. 2A, the bit line BL extending parallel to the bit line BL illustrated in FIG. 2A in the direction along the Y direction.

The block insulating layer BK and the tunnel insulating layer TN of the memory layer ME and the core layer CR are, for example, silicon oxide layers. The charge storage layer CT of the memory layer ME is, for example, a silicon nitride layer. The channel layer CN and the cap layer CP are, for example, semiconductor layers such as polysilicon layers or amorphous silicon layers.

As illustrated in FIG. 2C, with the above-described configuration, the memory cells MC are formed in portions of the side surface of the pillar PL facing the word lines WL, respectively. A predetermined voltage is applied from the word line WL to write and read data into and from the memory cell MC.

In addition, as illustrated in FIG. 2B, select gates STD are formed in portions in which the side surface of the pillar PL faces the select gate lines SGD0 and SGD1 in layers above the word line WL, respectively. In addition, select gates STS are formed in portions in which the side surface of the pillar PL faces the select gate lines SGS0 and SGS1 in layers below the word line WL, respectively.

Predetermined voltages are applied from the select gate lines SGD and SGS to turn on or off the select gates STD and STS, respectively, such that the memory cells MC of the pillar PL to which the select gates STD and STS belong can be changed to a selected state or a non-selected state.

The metal element-containing layers 28 and 58 that cover the upper and lower surfaces of the word line WL and the like are also disposed on surfaces of the word line WL and the like facing the side surface of the pillar PL. The metal element-containing layer 58 is interposed between the word line WL and the pillar PL to function as the block insulating layer containing metal in the memory cell MC as described above.

As illustrated in FIG. 2E, a plurality of contacts CC and a plurality of columnar portions HR are disposed in the contact region ER. That is, the contact region ER illustrated in FIG. 2E is a portion in which the contacts CC are disposed and that has a function of leading out the word lines WL and the like in the contact region ER divided into the plurality of block regions BLK.

In addition, in the contact region ER, the source line SL includes an intermediate insulating layer SCO interposed between the upper source line DSLb and the lower source line DSLa instead of the intermediate source line BSL. The intermediate insulating layer SCO is, for example, a silicon oxide layer.

Therefore, the plate-shaped portion LI penetrates the stacked body LM and the upper source line DSLb, and reaches the intermediate insulating layer SCO in the contact region ER.

The individual contacts CC extend to different depth positions in the stacked body LM to reach the word line WL or the select gate lines SGD and SGS to be connected.

As illustrated in FIGS. 2D and 2E, each of the contacts CC includes an extension portion CCt that extends in the stacked body LM in the stacking direction of the stacked body LM and an expansion portion CCp that spreads in a flat shape in the word line WL or the select gate lines SGD and SGS to be connected.

The extension portion CCt and the expansion portion CCp include a conductive layer 25. The conductive layer 25 may be, for example, a tungsten layer regardless of a conductive material forming the word line WL and the select gate lines SGD and SGS.

The conductive layer 25 in the extension portion CCt and the expansion portion CCp is connected to an upper layer wiring MX disposed in the insulating layer 53 through a plug V0 disposed in the insulating layer 52. The upper layer wiring MX is electrically connected to the peripheral circuit CBA (refer to FIGS. 1A and 1B).

In addition, among the extension portion CCt and the expansion portion CCp, a side wall of the extension portion CCt is covered with an insulating layer 55 such as a silicon oxide layer. As a result, the contact CC is prevented from being electrically connected to the word line WL or the like other than the word line WL or the select gate lines SGD and SGS to be connected.

In addition, the extension portion CCt has, for example, a tapered shape in which the diameter and the cross-sectional area decrease from the upper end portion toward the lower end portion. Alternatively, the extension portion CCt has, for example, a bowing shape in which the diameter and the cross-sectional area are the maximum at a predetermined position between the upper end portion and the lower end portion.

An end surface of the expansion portion CCp that spreads in the word line WL or the select gate lines SGD and SGS to be connected is connected to the word line WL or the like through the metal element-containing layers 28 and 58 covering the word line WL or the like to be connected. Among the metal element-containing layers 28 and 58, the metal element-containing layer 58 is an insulating layer but is a sufficiently thin layer. Therefore, even when the metal element-containing layer 58 is interposed, electrical connection of the contact CC to the word line WL or the like to be connected through the expansion portion CCp can be obtained.

In addition, the expansion portion CCp spreads in the word line WL or the select gate lines SGD and SGS to be connected by substantially the same distance in all the directions of the XY plane. In addition, center points of the expansion portion CCp and the extension portion CCt when seen from the stacking direction of the stacked body LM substantially match with each other. Accordingly, when the expansion portion CCp and the extension portion CCt have, for example, a circular cross-sectional shape in the direction along the stacking direction of the stacked body LM, that is, the direction along the XY plane, the outer edge portions of the expansion portion CCp and the extension portion CCt are substantially concentrically disposed.

With the above-described configuration, the word line WL in each layer and the select gate lines SGD and SGS in the layers above and below the word line WL can be electrically led out from one end side or the other end side of the stacked body LM in the X direction. That is, with the above-described configuration, a predetermined voltage is applied from the peripheral circuit CBA to the memory cell MC through the upper layer wiring MX, the contact CC, the word line WL, and the like such that the memory cell MC can operate as a memory element.

At least one insulating layer OL positioned below each of the contacts CC, that is, below the word line WL or the like to which the contact CC is to be connected may have bending in the stacking direction. As a result, among the word lines WL or the like adjacent in the stacking direction to the insulating layer OL bent in the stacking direction, the word line WL or the like positioned in the convex direction of the bending of the insulating layer OL may be blocked, and the word line WL or the like positioned in the concave direction of the bending of the insulating layer OL may include a void VD. In a blocked portion JM formed in the word line WL or the like, both of the word line WL and the metal element-containing layer 28 may be disconnected. In this case, the word lines WL in the same layer facing each other with respect to the blocked portion JM do not have electrical connection.

In the example of FIG. 2D, the insulating layer OL in the layer positioned below the word line WL to which the contact CC is to be connected by two layers is bent in an upwardly convex shape. As a result, the word line WL in the layer positioned below the word line WL to which the contact CC is to be connected by one layer is blocked due to the bending of the insulating layer OL of the lower layer. In addition, the word line WL in the layer below the insulating layer OL having the bending includes the void VD.

The plurality of columnar portions HR disposed in the contact region ER penetrate the stacked body LM, the upper source line DSLb, and the intermediate insulating layer SCO, and reach the lower source line DSLa. These columnar portions HR are dispersed and disposed in the contact region ER, and when the stacked body LM is formed of the stacked body where the sacrificial layers and the insulating layers are stacked in a manufacturing process of the semiconductor memory device 1 described below, function to support these configurations and do not contribute to the function of the semiconductor memory device 1.

Therefore, each of the plurality of columnar portions HR is a single insulating layer 59 such as a silicon oxide layer extending in the stacked body LM in the stacking direction, and is not electrically connected to the source line SL.

Each of the columnar portions HR has, for example, a circular shape, an elliptical shape, or an oval shape as a cross-sectional shape in a direction along the stacking direction of the stacked body LM, that is, in a direction along the XY plane.

In addition, in the columnar portion HR, each of a portion that penetrates the stacked body LMa and a portion that penetrates the stacked body LMb has a tapered shape in which the diameter and the cross-sectional area decrease from the upper layer side toward the lower layer side. Alternatively, in the columnar portion HR, each of the portion that penetrates the stacked body LMa and the portion that penetrates the stacked body LMb has, for example, a bowing shape in which the diameter and the cross-sectional area are the maximum values at a predetermined position between the upper layer side and the lower layer side.

FIG. 3 is a cross-sectional view taken along the XY plane illustrating the example of the configuration of the semiconductor memory device 1 according to the embodiment.

More specifically, FIG. 3 is an XY cross-sectional view at the height position of the select gate line SGD, illustrating a part of the memory region MR and the contact region ER between the plate-shaped portions LI adjacent to each other in the Y direction.

As illustrated in FIG. 3, in the memory region MR, the plurality of pillars PL have, for example, a staggered arrangement when seen from the stacking direction of the stacked body LM.

In addition, in the contact region ER, while avoiding interference with the plate-shaped portions LI and the contacts CC, the plurality of columnar portions HR have, for example, a staggered or grid-like arrangement when seen from the stacking direction of the stacked body LM.

At the same height position of the stacked body LM, the cross-sectional area of the columnar portion HR in the direction along the XY plane is larger than, for example, the cross-sectional area of the pillar PL in the direction along the XY plane. In addition, a pitch between the plurality of columnar portions HR is larger than, for example, a pitch between the plurality of pillars PL, and a disposition density of the columnar portions HR per unit area of the word line WL in the stacked body LM is lower than a disposition density of the pillars PL per unit area of the word line WL.

This way, for example, by configuring the cross-sectional area of the pillar PL to be smaller than that of the columnar portion HR and by making the pitch narrow, a large number of memory cells MC can be formed at a high density in the stacked body LM having a predetermined size, and the memory capacity of the semiconductor memory device 1 can be increased. On the other hand, the columnar portion HR is used exclusively to support the stacked body LM. Therefore, for example, by not adopting an accurate configuration having a small cross-sectional area and a narrow pitch unlike the pillar PL, the processing accuracy for forming the columnar portion HR can be relaxed.

In addition, in the contact region ER, a plurality of contacts CC are disposed in a region surrounded by the plurality of columnar portions HR.

In a direction from the left side to the right side of the paper plane, that is, away from the memory region MR, the contacts CC are connected to the word lines WL or the select gate lines SGD and SGS on the lower layer side of the stacked body LM. In addition, in the example of FIG. 3, the stacked body LM includes two select gate lines SGD, and in a region of each of the select gate lines SGD divided by the plurality of separation layers SHE, two contacts CC connected to the select gate line SGD are disposed.

As described above, each of the contacts CC includes the extension portion CCt and the expansion portion CCp. In FIG. 3, the expansion portion CCp that spreads at a predetermined depth position of the stacked body LM is represented by a broken line.

As described above, the extension portion CCt and the expansion portion CCp have, for example, a circular shape on the XY plane, respectively, and are concentrically disposed. In addition, the expansion portion CCp may have a diameter that is larger than or equal to a maximum diameter of the extension portion CCt of the contact CC having a tapered shape or a bowing shape and is smaller than or equal to the pitch between the columnar portions HR surrounding the contact CC.

In order to avoid contact between the contacts CC, the columnar portion HR is not disposed at the position of the contact CC. Accordingly, in the periphery of the contact CC, a pitch between the columnar portions HR is wider than that in the other portions where the columnar portions HR have a periodic arrangement, for example, a staggered or a grid-like arrangement.

In addition, as illustrated in FIG. 2D, by bending any one of the insulating layers OL on the lower layer side of each of the contacts CC, the word line WL or the like in the layer above and below the insulating layer OL may include the blocked portion JM or the void VD. The blocked portion JM or the void VD of the word line WL or the like may be interposed and present between the contact CC connected to the word line WL or the like including the blocked portion JM or the void VD and the memory cell MC corresponding to the contact CC.

However, as indicated by a plurality of arrows in FIG. 3, a plurality of conductive paths PSe that bypass the blocked portion JM or the void VD interposed in the middle of the word line WL may be present between the contact CC and the memory cell MC. Accordingly, even when the blocked portion JM or the void VD is interposed in the word line WL between the contact CC and the memory cell MC, electrical connection between the contact CC and the memory cell MC is maintained.

### Method of Manufacturing Semiconductor Memory Device

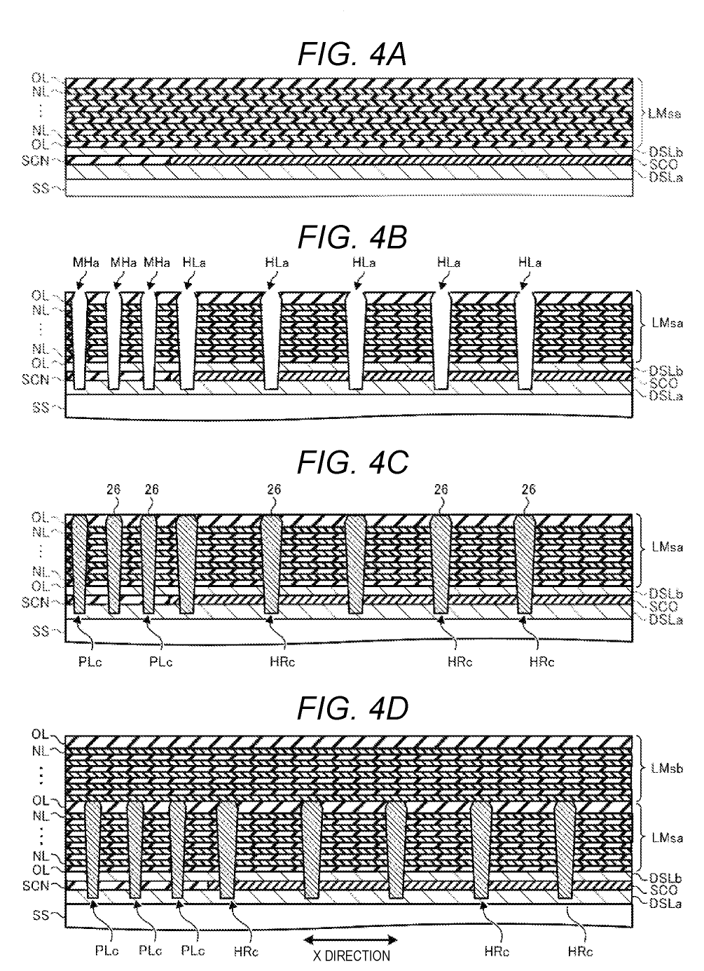

Next, a method of manufacturing the semiconductor memory device 1 according to the embodiment will be described using FIGS. 4A to 11D. FIGS. 4A to 11D are cross-sectional views sequentially illustrating a portion of a procedure of the method of manufacturing the semiconductor memory device 1 according to the embodiment.

First, FIGS. 4A to 4D illustrate a stacked body LMsa that is a lower layer portion of the stacked body LM where the word lines WL are not yet formed, and a state where various configurations are formed in the stacked body LMsa. FIGS. 4A to 4D are cross-sectional views taken along the X direction illustrating regions that subsequently form the memory region MR and the contact region ER.

As illustrated in FIG. 4A, the lower source line DSLa, an intermediate sacrificial layer SCN or the intermediate insulating layer SCO, and the upper source line DSLb are formed in this order on a supporting substrate SS.

A semiconductor substrate such as a silicon substrate, an insulating substrate such as a ceramic substrate, a conductive substrate, or the like may be used as the supporting substrate SS. The insulating layer 60 (refer to FIGS. 2A to 2E and the like) described above may be formed on an upper surface side of the supporting substrate SS.

The intermediate sacrificial layer SCN is formed in a region on the supporting substrate SS that subsequently forms the memory region MR, and the intermediate insulating layer SCO is formed in a region on the supporting substrate SS that subsequently forms the contact region ER. The intermediate sacrificial layer SCN is, for example, a silicon nitride layer, and is a layer that is subsequently replaced with a polysilicon layer or the like to form the intermediate source line BSL. The intermediate insulating layer SCO is, for example, a silicon oxide layer as described above.

In addition, the stacked body LMsa in which a plurality of insulating layers NL and a plurality of insulating layers OL are alternately stacked is formed on the upper source line DSLb. The insulating layer NL is, for example, a silicon nitride layer, and functions as a sacrificial layer that is subsequently replaced with a conductive material to form the word line WL or the select gate line SGS.

As illustrated in FIG. 4B, for example, a plurality of memory holes MHa and a plurality of holes HLa extending in the stacked body LMsa in the stacking direction are formed.

The memory hole MHa is a portion that subsequently forms a lower structure of the pillar PL. The plurality of memory holes MHa are disposed in a region that subsequently forms the memory region MR, penetrate the stacked body LMsa, the upper source line DSLb, and the intermediate sacrificial layer SCN, and reach the lower source line DSLa.

The hole HLa is a portion that subsequently forms a lower structure of the columnar portion HR. The plurality of holes HLa are disposed in a region that subsequently forms the contact region ER, penetrate the stacked body LMsa, the upper source line DSLb, and the intermediate insulating layer SCO, and reach the lower source line DSLa.

As illustrated in FIG. 4C, the memory holes MHa and the holes HLa are filled with a sacrificial layer 26 such as an amorphous silicon layer. As a result, pillars PLc obtained by filling the plurality of the memory holes MHa with the sacrificial layers 26 are formed in a region that subsequently forms the memory region MR. In addition, columnar portions HRc obtained by filling a plurality of holes HRa with the sacrificial layer 26 are formed in a region that subsequently forms the contact region ER.

As illustrated in FIG. 4D, a stacked body LMsb that covers the stacked body LMsa and in which a plurality of insulating layers NL and a plurality of insulating layers OL are alternately stacked is formed.

The stacked body LMsb is an upper layer portion of the stacked body LM where the word lines WL are not yet formed. The insulating layer NL of the stacked body LMsb functions as a sacrificial layer that is subsequently replaced with the conductive material to form the word line WL or the select gate line SGD.

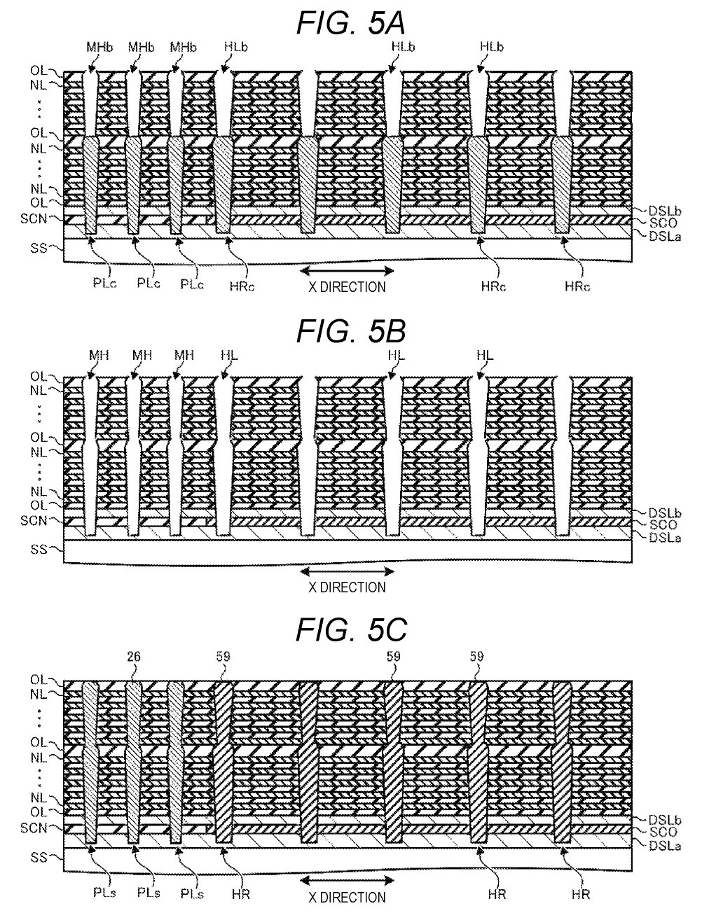

Next, FIGS. 5A to 5C illustrate a state where various configurations are formed in the stacked bodies LMsa and LMsb. As in FIGS. 4A to 4D, FIGS. 5A to 5C are cross-sectional views taken along the X direction illustrating regions that subsequently form the memory region MR and the contact region ER.

As illustrated in FIG. 5A, for example, a plurality of memory holes MHb and a plurality of holes HLb extending in the stacked body LMsb in the stacking direction are formed.

The memory hole MHb is a portion that subsequently forms an upper structure of the pillar PL. The plurality of memory holes MHb are disposed in a region that subsequently forms the memory region MR, penetrate the stacked body LMsb, and reach upper end portions of the pillars PLc formed in the stacked body LMsa, respectively.

The hole HLb is a portion that subsequently forms an upper structure of the columnar portion HR. The plurality of holes HLb are disposed in a region that subsequently forms the contact region ER, penetrate the stacked body LMsb, and reach upper end portions of the columnar portions HRc formed in the stacked body LMsa, respectively.

As illustrated in FIG. 5B, the sacrificial layer 26 is removed from the pillar PLc at the bottom of the memory hole MHb. As a result, the memory holes MHa are formed at the bottoms of the plurality of memory holes MHb, respectively, and a plurality of memory holes MH that penetrate the stacked bodies LMsb and LMsa, the upper source line DSLb, and the intermediate sacrificial layer SCN and reach the lower source line DSLa are formed.

Concurrently, the sacrificial layer 26 is removed from the columnar portion HRc at the bottom of the hole HLb. As a result, the hole HLa is formed at each of the bottoms of the plurality of holes HLb, and a plurality of holes HL that penetrate the stacked bodies LMsb and LMsa, the upper source line DSLb, and the intermediate insulating layer SCO and reach the lower source line DSLa are formed.

As illustrated in FIG. 5C, the plurality of memory holes MH are filled with the sacrificial layer 26 again to form a plurality of pillars PLs that penetrate the stacked bodies LMsa and LMsb and extend. In addition, the plurality of holes HL are filled with the insulating layer 59 to form the plurality of columnar portions HR.

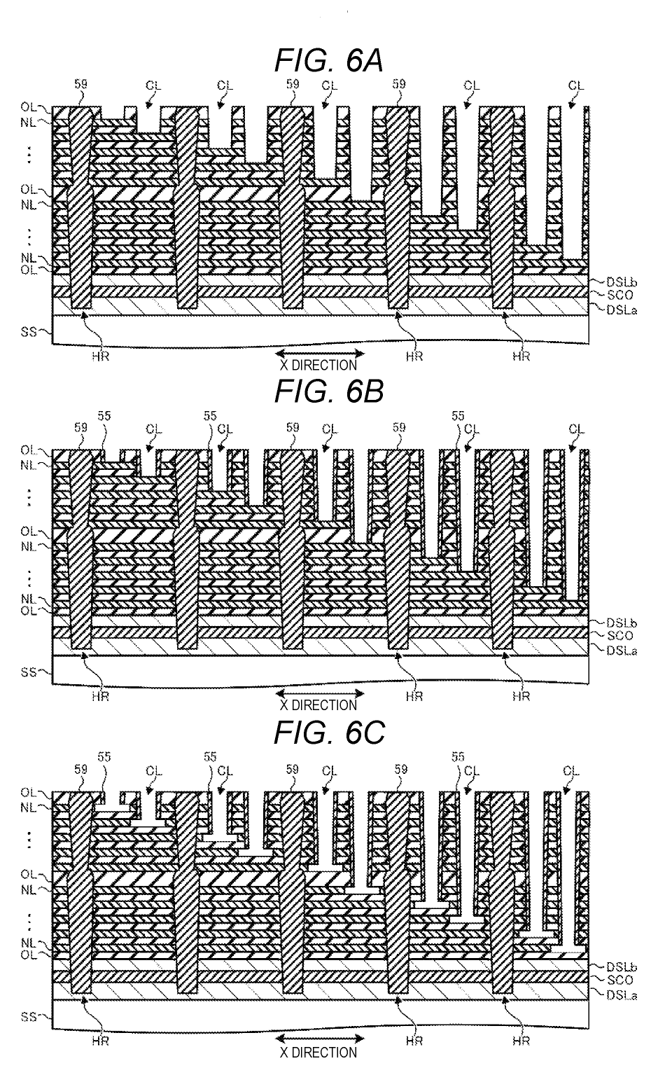

Next, a state where a configuration that subsequently forms the contact CC is formed in a partial region of the stacked bodies LMsa and LMsb will be described using FIGS. 6A to 6C. FIGS. 6A to 6C are cross-sectional views taken along the X direction illustrating a region that subsequently forms the contact region ER.

As illustrated in FIG. 6A, a plurality of contact holes CL that reach insulating layers NL at different depths are formed in a region that subsequently forms the contact region ER.

As illustrated in FIG. 6B, a side wall of each of the contact holes CL is covered with the insulating layer 55. More specifically, the insulating layer 55 that covers the side wall and a bottom surface of the contact hole CL is formed, and the insulating layer 55 of the bottom surface is removed. At this time, the insulating layer 55 is also formed on an upper surface of the stacked body LMsb, and when the insulating layer 55 of the bottom surface of the contact hole CL is removed, the insulating layer 55 is also removed from the upper surface of the stacked body LMsb.

As illustrated in FIG. 6C, by allowing a removal solution for the insulating layer NL such as hot phosphoric acid to flow into each of the contact holes CL, the insulating layer NL exposed to the bottom surface of the contact hole CL is retracted by a predetermined distance. At this time, the side wall of the contact hole CL is covered with the insulating layer 55, which prevents the insulating layer NL of the upper layer side from being retracted together.

At this time, wet etching using the removal solution such as hot phosphoric acid isotropically progresses. Therefore, the insulating layer NL that is removed on the bottom surface of the contact hole CL is removed from the side wall of the contact hole CL to the periphery by a retraction amount of substantially the same distance.

As a result, an outer edge portion of the expansion portion CCp that is subsequently formed surrounds the extension portion CCt at positions at substantially the same distance from a center point of the expansion portion CCp when seen from the stacking direction of the stacked bodies LMsa and LMsb. In addition, the center points of the extension portion CCt and the expansion portion CCp when seen from the stacking direction substantially match with each other, and the extension portion CCt and the expansion portion CCp are substantially concentrically disposed.

The retraction distance of the insulating layer NL in the lower end portion of the contact hole CL is preferably larger than or equal to the maximum diameter of the extension portion of the contact hole CL extending in the stacked bodies LMsa and LMsb, and is preferably smaller than or equal to the pitch between the columnar portions HR surrounding the contact hole CL.

Next, by filling the contact holes CL with the conductive material such as tungsten, the plurality of contacts CC including the extension portion CCt and the expansion portion CCp are formed.

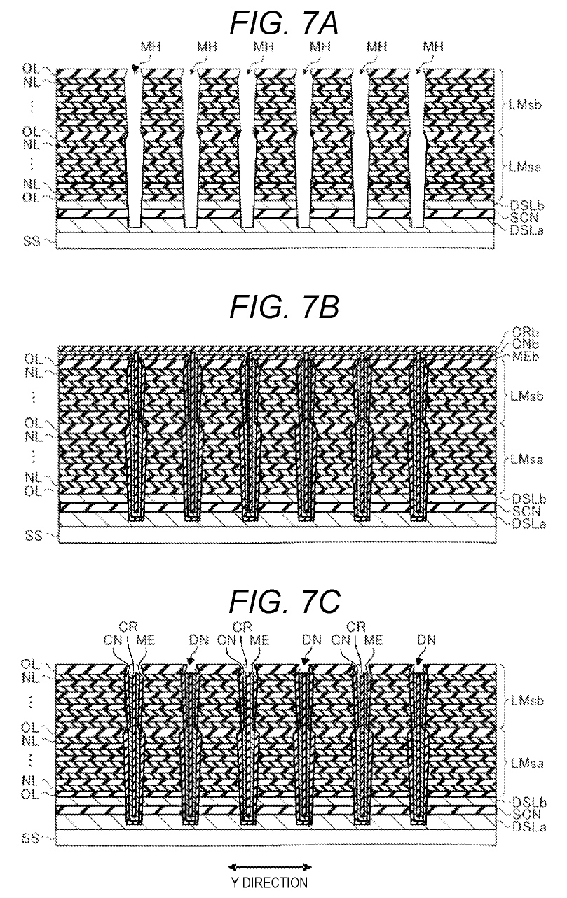

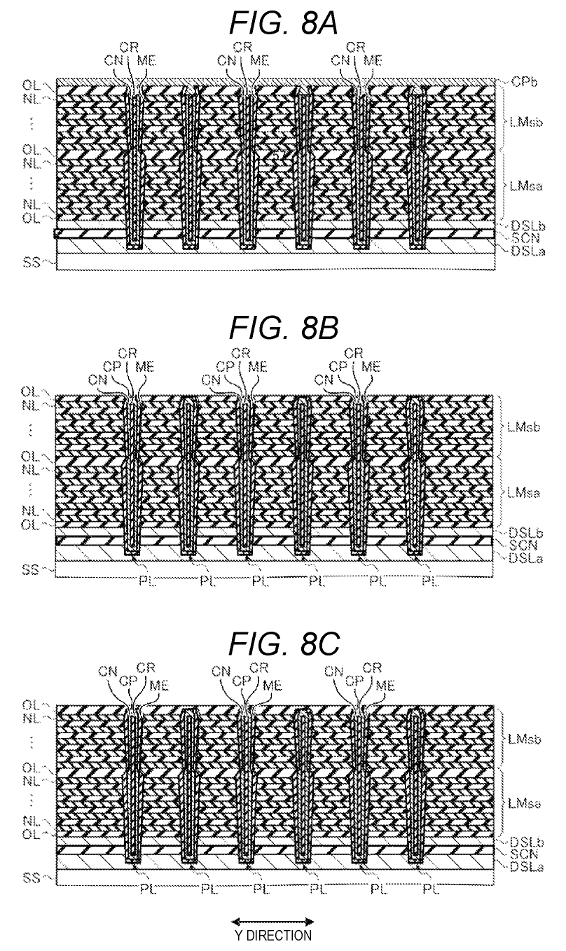

Next, a state where the multilayer structure is formed in the memory holes MH to form the pillars PL will be described using FIGS. 7A to 8C. FIGS. 7A to 8C are cross-sectional views taken along the Y direction illustrating the region that subsequently forms the memory region MR.

As illustrated in FIG. 7A, the sacrificial layers 26 are removed from the plurality of pillars PLs formed through the process of FIG. 5C, and the plurality of memory holes MH are formed again.

As illustrated in FIG. 7B, a multilayer insulating layer MEb, a semiconductor layer CNb, and an insulating layer CRb are formed in this order in the memory hole MH. As a result, the multilayer insulating layer MEb and the semiconductor layer CNb are disposed on the side surface of the memory hole MH and on the bottom surface thereof from which the lower source line DSLa is exposed, and a central portion of the memory hole MH is filled with the insulating layer CRb.

The multilayer insulating layer MEb is an insulating layer having a multilayer structure that subsequently forms the memory layer ME. The semiconductor layer CNb is a layer that subsequently forms the channel layer CN. The insulating layer CRb is a silicon oxide layer or the like that subsequently forms the core layer CR.

The multilayer insulating layer MEb, the semiconductor layer CNb, and the insulating layer CRb are also formed in this order on the upper surface of the stacked body LMsb.

As illustrated in FIG. 7C, in the region that subsequently forms the memory region MR, the insulating layer CRb, the semiconductor layer CNb, and the multilayer insulating layer MEb are sequentially etched back to be removed from the upper surface of the stacked body LMsb, and a depression DN obtained by removing the insulating layer CRb and the semiconductor layer CNb is formed in the upper end portion of the memory hole MH.

As a result, the memory layer ME, the channel layer CN, and the core layer CR are formed in the memory hole MH in order from the outer peripheral side.

As illustrated in FIG. 8A, in the region that subsequently forms the memory region MR, a semiconductor layer CPb is formed in the depression DN of the upper end portion of the memory hole MH. The semiconductor layer CPb is a layer that subsequently forms the cap layer CP. The semiconductor layer CPb is also formed on the upper surface of the stacked body LMsb.

As illustrated in FIG. 8B, in the region that subsequently forms the memory region MR, the semiconductor layer CPb on the upper surface of the stacked body LMsb is removed by CMP or the like, and the cap layer CP is formed in the upper end portion of the memory hole MH.

As illustrated in FIG. 8C, the insulating layer OL on the uppermost layer of the stacked body LMsb thinned by CMP or the like is stacked.

As a result, the pillar PL in which the cap layer CP is buried in the insulating layer OL of the uppermost layer is formed. Meanwhile, at this time, the memory layer ME covers the entire side wall of the pillar PL, and a portion of the side surface of the channel layer CN is not exposed from the memory layer ME.

Due to the CMP process in FIG. 7B and the stacking of the insulating layer OL in FIG. 8C, the upper end portion of the columnar portion HR may also be buried in the insulating layer OL of the uppermost layer.

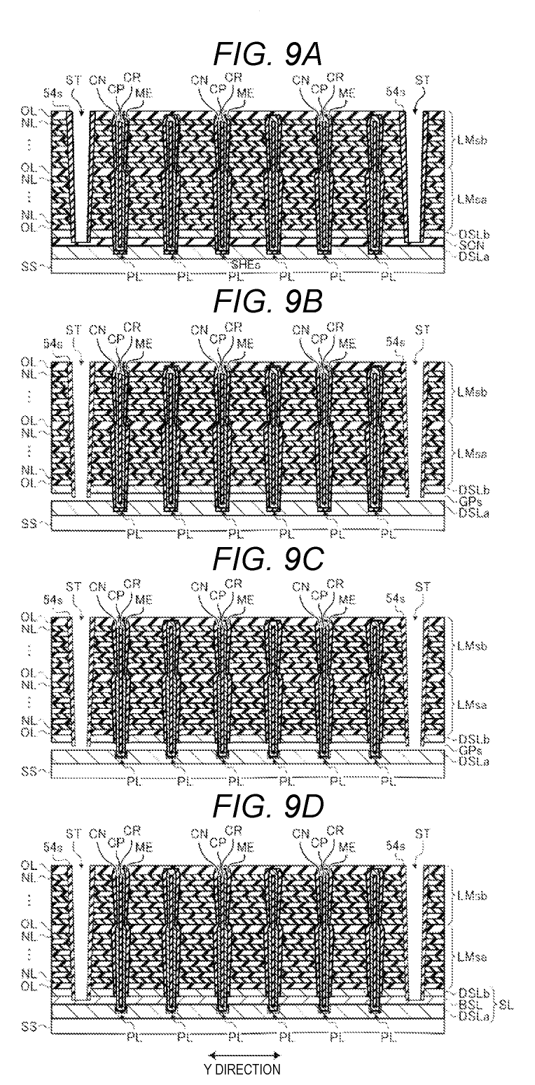

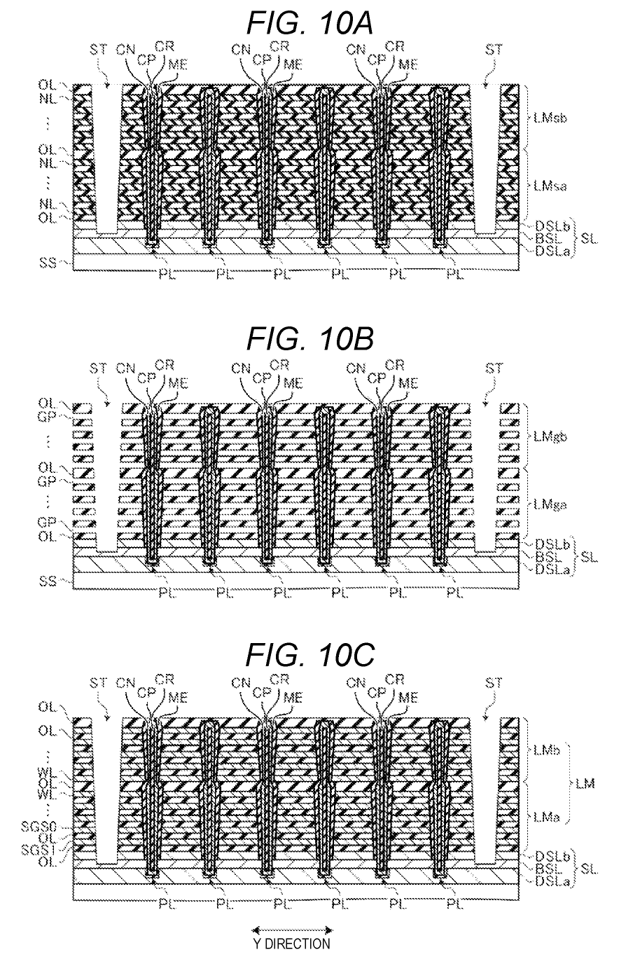

Next, a state where the source line SL and the word line WL are formed will be described using FIGS. 9A to 10C. As in FIGS. 7A to 8C, FIGS. 9A to 10C are cross-sectional views taken along the Y direction illustrating the region that subsequently forms the memory region MR.

As illustrated in FIG. 9A, a slit ST that penetrates the stacked bodies LMsb and LMsa and the upper source line DSLb, and reaches the intermediate sacrificial layer SCN is formed. In addition, an insulating layer 54s is formed on side walls of the slit ST facing each other in the Y direction.

The slit ST has a longitudinal section in the Y direction having a tapered shape or a bowing shape, and also extends in the direction along the X direction in the stacked bodies LMsa and LMsb. Therefore, in the contact region ER (not illustrated), a lower end portion of the slit ST reaches the intermediate insulating layer SCO.

As illustrated in FIG. 9B, for example, by allowing a removal solution for the intermediate sacrificial layer SCN such as hot phosphoric acid to flow through the slit ST of which the side wall is protected by the insulating layer 54s, the intermediate sacrificial layer SCN interposed between the lower source line DSLa and the upper source line DSLb is removed.

As a result, a gap layer GPs is formed between the lower source line DSLa and the upper source line DSLb. In addition, a portion of the memory layer ME of the outer peripheral portion of the pillar PL is exposed in the gap layer GPs.

As illustrated in FIG. 9C, by appropriately allowing a chemical solution to flow into the gap layer GPs through the slit ST, the block insulating layer BK, the charge storage layer CT, and the tunnel insulating layer TN (refer to FIGS. 2B and 2C) of the memory layer ME exposed in the gap layer GPs are sequentially removed. As a result, the memory layer ME is removed from a part of the side wall of the pillar PL, and a part of the channel layer CN on the inner side is exposed in the gap layer GPs.

As illustrated in FIG. 9D, for example, by injecting raw material gas such as amorphous silicon from the slit ST of which the side wall is protected by the insulating layer 54s, the gap layer GPs is filled with the amorphous silicon or the like. In addition, by performing a heating treatment on the supporting substrate SS to polycrystallize the amorphous silicon filling the gap layer GPs, the intermediate source line BSL containing polysilicon or the like is formed.

As a result, a part of the channel layer CN of the pillar PL is connected to the source line SL on the side surface through the intermediate source line BSL.

At this time, in the contact region ER (not illustrated), the gap layer GPs is not formed between the lower source line DSLa and the upper source line DSLb. In addition, the intermediate source line BSL is not formed.

As illustrated in FIG. 10A, the insulating layer 54s on the side wall of the slit ST is temporarily removed.

As illustrated in FIG. 10B, for example, by allowing a removal solution for the insulating layer NL such as hot phosphoric acid to flow from the slit ST into the stacked bodies LMsa and LMsb, the insulating layer NL of the stacked bodies LMsa and LMsb is removed. As a result, stacked bodies LMga and LMgb including a plurality of gap layers GP obtained by removing the insulating layers NL between the insulating layers OL are formed.

At this time, the stacked bodies LMga and LMgb including the plurality of gap layers GP have a weak structure. In the region that subsequently forms the memory region MR, the plurality of pillars PL support the weak stacked bodies LMga and LMgb. In addition, in the region that subsequently forms the contact region ER, the plurality of columnar portions HR support the stacked bodies LMga and LMgb.

With the support structure of the pillar PL and the columnar portion HR, the remaining insulating layer OL is prevented from being bent, and the stacked bodies LMga and LMgb are prevented from being distorted or collapsed.

As illustrated in FIG. 10C, for example, raw material gas of a conductive material such as tungsten or molybdenum is injected from the slit ST into the stacked bodies LMga and LMgb, and the gap layers GP of the stacked bodies LMga and LMgb are filled with the conductive material to form a plurality of word lines WL and the like.

Although not illustrated in the drawing, before the formation of the plurality of word lines WL and the like, the metal element-containing layers 58 and 28 covering the upper and lower surfaces and the like of the gap layers GP are formed in this order.

From the above, the stacked body LM including the stacked bodies LMa and LMb in which the plurality of word lines WL and the like and the plurality of insulating layers OL are alternately stacked is formed.

As described above, the process of forming the intermediate source line BSL from the intermediate sacrificial layer SCN and the process of forming the word line WL or the like from the insulating layer NL will also be referred to as a replacement process.

Next, the insulating layer 54 is formed on the side wall of the slit ST, and the insulating layer 54 is filled with the conductive layer 24 to form the plate-shaped portion LI. Meanwhile, a plate-shaped member may be formed by filling the slit ST with the insulating layer 54 or the like without forming the conductive layer 24.

In addition, by forming a groove that penetrates the uppermost layer of the stacked body LMb and the second conductive layer from the uppermost layer, and filling the groove with the insulating layer 56, the separation layer SHE that divides these conductive layers in the pattern of the select gate lines SGD is formed.

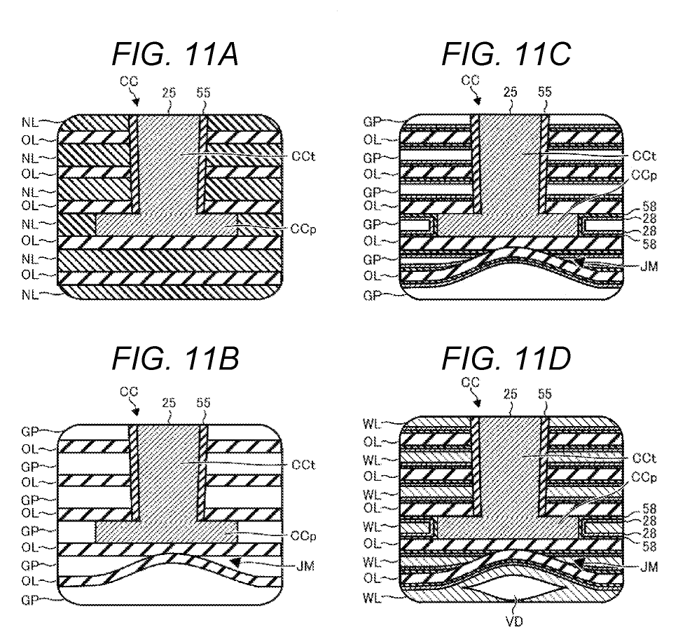

Next, the details of the replacement process of the above-described word lines WL and the like in the contact region ER will be described using FIGS. 11A to 11D. FIGS. 11A to 11D are enlarged cross-sectional views illustrating the contact CC at the height position of the insulating layer NL or the word line WL.

As illustrated in FIG. 11A, by filling the contact hole CL with the conductive layer 25 after the process of FIG. 6C, the contact CC that includes the extension portion CCt and the expansion portion CCp and reaches a predetermined insulating layer NL is formed. The expansion portion CCp spreads in the insulating layer NL that the contact CC reaches.

As illustrated in FIG. 11B, the insulating layer NL is removed through the process of FIG. 10B, and the stacked bodies LMga and LMgb including the plurality of gap layers GP and having a weak structure are formed. In the region that subsequently forms the contact region ER, the stacked bodies LMga and LMgb are supported by the plurality of columnar portions HR as described above. Meanwhile, at the arrangement positions of the contacts CC, the contacts CC support the stacked bodies LMga and LMgb instead of the columnar portions HR.

However, each of the contacts CC is present only up to a target depth position that the insulating layer NL is desired to reach, and in a region of the stacked bodies LMga and LMgb below each of the contacts CC, the pitch between the columnar portions HR is wider than that in the other regions. Accordingly, in the region below each of the contacts CC, the remaining insulating layers OL may be bent, or the stacked bodies LMga and LMgb may be distorted.

In the example of FIG. 11B, the insulating layer OL positioned two layers below the gap layer GP where the expansion portion CCp of the contact CC is positioned is bent. As a result, the gap layer GP above the bent insulating layer OL, that is, the gap layer GP positioned one layer below the gap layer GP where the expansion portion CCp of the contact CC is positioned is blocked, and the gap layer GP below the bent insulating layer OL is spread in the stacking direction of the stacked bodies LMga and LMgb.

Meanwhile, this way, for example, even when the insulating layer OL in the vicinity of the lower end portion of the contact CC among the plurality of insulating layers OL below the contact CC is bent, in the target gap layer GP that the contact CC is desired to reach, the influence of the bent insulating layer OL is reduced to ensure the gap using the expansion portion CCp.

As illustrated in FIG. 11C, the metal element-containing layers 58 and 28 are formed in this order on both surfaces of the gap layer GP in the vertical direction. At this time, the metal element-containing layers 58 and 28 are also formed on the end surface of the expansion portion CCp of the contact CC exposed in the gap layer GP and on the side surface of the pillar PL.

Meanwhile, in the blocked portion JM of the gap layer GP of which a part is blocked by the bent insulating layer OL, formation failure of the metal element-containing layers 58 and 28 may occur.

As illustrated in FIG. 11D, the gap layer GP covered with the metal element-containing layers 58 and 28 is filled with a conductive material such as tungsten through the process of FIG. 10C to form the stacked body LM including the plurality of word lines WL and the like.

Even at this time, the blocked portion JM of the gap layer GP of which a part is blocked by the bent insulating layer OL is not filled with the conductive material, which may cause disconnection of the word line WL or the like. In addition, in the gap layer GP that is spread in the stacking direction of the stacked bodies LMga and LMgb by the bent insulating layer OL, the gap layer GP is not completely filled with the conductive material, and the formed word line WL or the like may include the void VD.

Meanwhile, even in the contact CC including the bent insulating layer OL below the contact CC, as described above, the influence of the bending of the insulating layer OL on the gap layer GP that the contact CC reaches is reduced by the expansion portion CCp in the contact CC. Therefore, formation failure of the word line WL or the like is also prevented. Accordingly, electrical connection between the word line WL to be connected and the contact CC can be ensured.

At this time, as described above, the expansion portion CCp has a diameter that is larger than or equal to the maximum diameter of the extension portion CCt. As a result, a sufficient effect of reducing the influence of the bending of the insulating layer OL in the target gap layer GP that the contact CC is desired to reach can be obtained. In addition, as described above, the expansion portion CCp has a diameter that is smaller than or equal to the pitch between the columnar portions HR surrounding the contact CC. As a result, contact between the expansion portion CCp of the contact CC and the columnar portion HR can be prevented.

In addition, even in the contact CC to which the word line WL or the like including the blocked portion JM or the void VD caused by the bending of the insulating layer OL is to be connected, as described above, electrical connection of the corresponding memory cell MC is maintained by the conductive paths PSe (refer to FIG. 3) that bypass the blocked portion JM and the void VD.

Next, the insulating layer 52 is formed on the upper surface of the stacked body LM, and the plug V0 that penetrates the insulating layer 52 and is connected to the contact CC is formed. In addition, the plug CH that penetrates the insulating layer 52 and is connected to the pillar PL is formed. Further, the insulating layer 53 is formed on the insulating layer 52, and the upper layer wirings MX, the bit lines BL, and the like connected to the plugs V0 and CH are formed. In addition, an electrode pad or the like for electrical connection to the peripheral circuit CBA is formed on the upper surface of the insulating layer 53.

Further, for example, by using a dual damascene method or the like, the plugs V0 and CH, the upper layer wirings MX, the bit lines BL, and the like may be collectively formed.

In addition, the peripheral circuit CBA is formed on a semiconductor substrate SB separate from the supporting substrate SS on which the stacked body LM is formed, and is covered with the insulating layer 40. A contact, a via, a wiring, and the like for leading out the peripheral circuit CBA to the surface of the insulating layer 40 are formed in the insulating layer 40, and are connected to the electrode pad and the like formed on the upper surface of the insulating layer 40.

Next, the supporting substrate SS and the semiconductor substrate SB are bonded to each other by the insulating layers 50 and 40 provided in the supporting substrate SS and the semiconductor substrate SB, respectively, to connect the electrode pads in the insulating layers 50 and 40. Next, the supporting substrate SS is removed to expose the source line SL, and the electrode film EL is connected through the insulating layer 60 in which the plugs PG are formed.

From the above, the semiconductor memory device 1 according to the embodiment is manufactured.

### Comparative Example

In a semiconductor memory device such as a three-dimensional non-volatile memory, for example, by stacking a plurality of sacrificial layers and replacing the sacrificial layers with word lines and the like, memory cells that are three-dimensionally arranged in the word lines stacked in multiple layers are formed. In addition, by forming a plurality of contacts to be connected to the word lines, respectively, the word lines and the like stacked in multiple stages can be electrically led out.

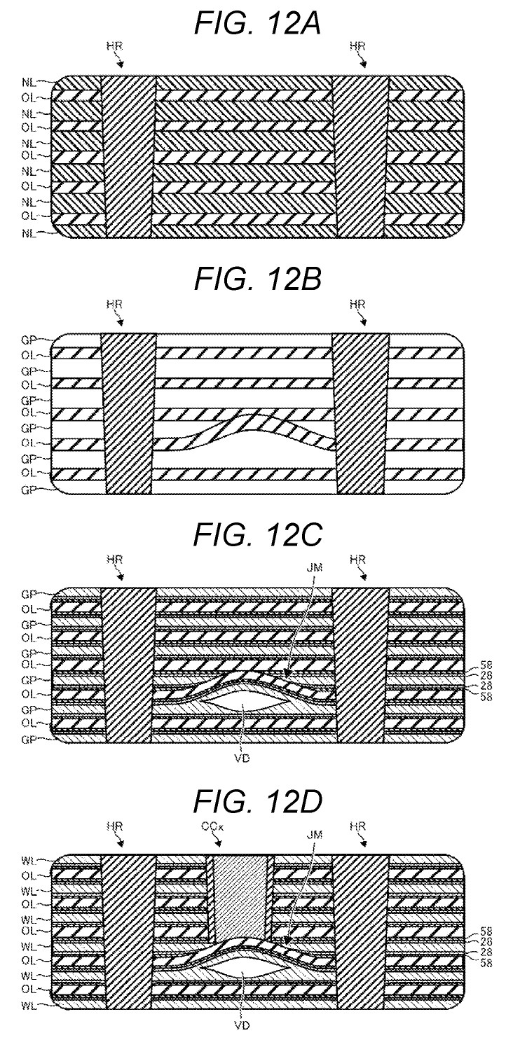

In the contact region, a plurality of columnar portions are dispersed and disposed in advance, and function as supporting columns when the plurality of sacrificial layers are replaced with the word lines and the like. However, the columnar portions are not disposed at the arrangement positions of the individual contacts, and a pitch between the columnar portions is wide. Therefore, the remaining insulating layers in the stacked body may be bent. This state is illustrated in FIGS. 12A to 12D.

FIGS. 12A to 12D are cross-sectional views illustrating a part of a procedure of a method of forming a contact CCx according to Comparative Example. As illustrated in FIGS. 12A to 12D, the contact CCx according to Comparative Example is formed, for example, after the replacement process of the word lines WL and the like.

That is, as illustrated in FIG. 12A, before the replacement process, the plurality of columnar portions HR that penetrate the insulating layers NL and OL are formed. Among these, a pitch between the columnar portions HR in the formation region of the contact CCx at the center of the paper plane is wide. As illustrated in FIG. 12B, by removing the insulating layer NL, any insulating layer OL between the columnar portions HR having the wide pitch may be bent. As illustrated in FIG. 12C, the metal element-containing layers 58 and 28 are formed in this order in the gap layer GP, and the gap layer GP is further filled with the conductive material to form the word line WL or the like. At this time, each of the word lines WL in the layers above and below the bent insulating layer OL may include the blocked portion JM and the void VD. In the example of FIG. 12D, the contact CCx to which the word line WL including the blocked portion JM is to be connected is formed. In this case, the contact CCx cannot ensure electrical connection to the word line WL to be connected, and electrical connection failure may occur.

As described above, in the contact CCx according to Comparative Example, when the insulating layer OL in the vicinity of the target insulating layer NL that the contact CCx is desired to reach among the insulating layer OLs between the columnar portions HR having the wide pitch is bent, the target insulating layer NL includes the blocked portion JM or the void VD due to the influence of the bending of the insulating layer OL, and electrical connection failure to the contact CCx may occur.

In the semiconductor memory device 1 according to the embodiment, the contact includes: the extension portion CCt that extends in the stacked body LM in the stacking direction; and the expansion portion CCp that extends from the lower end portion of the extension portion CCt to the word line WL to be connected and is connected to the word line WL. As a result, during the replacement process, the blocking of the word line WL in the lower end portion of the contact CC can be prevented.

In the method of manufacturing the semiconductor memory device 1 according to the embodiment, the contact CC is formed before the formation of the stacked body LM through the replacement process. As a result, the expansion portion CCp in the contact CC prevents the gap layer GP that the contact CC reaches from being blocked during the replacement process.

### Modification Example

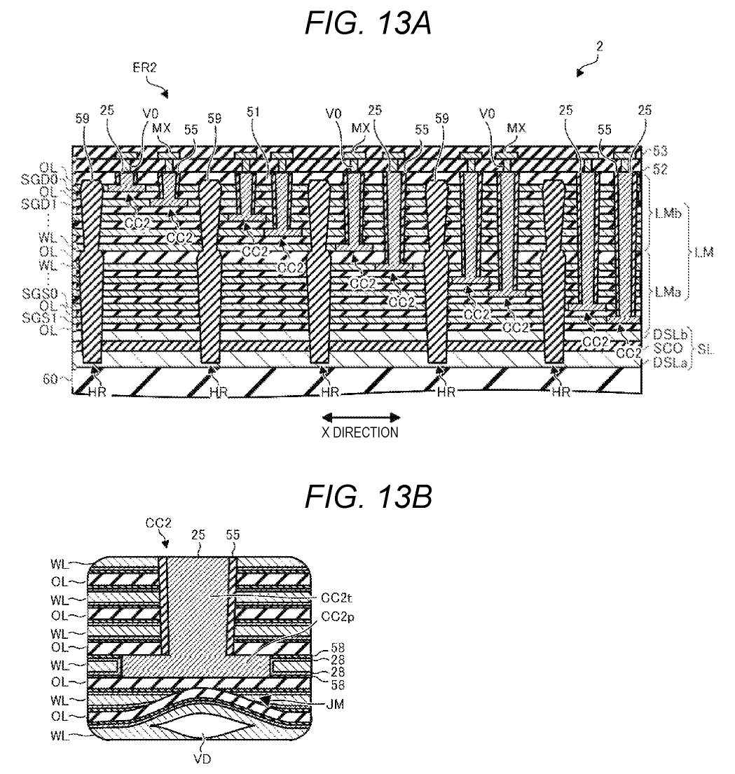

Next, a semiconductor memory device 2 according to a modification example of the embodiment will be described using FIGS. 13A to 15G. The semiconductor memory device 2 according to the modification example is different from the above-described embodiment, in that an expansion portion CC2p of a contact CC2 is connected to the word line WL or the like without the metal element-containing layer 58 to be interposed therebetween.

In the following drawings, the same reference numerals will be given to the same configuration as in the above-described embodiment, and the description thereof will not be repeated.

FIGS. 13A and 13B are diagrams illustrating an example of a configuration of the semiconductor memory device 2 according to the modification example of the embodiment. More specifically, FIG. 13A is a cross-sectional view taken along the X direction illustrating a contact region ER2 of the semiconductor memory device 2. FIG. 13B is an enlarged cross-sectional view illustrating the contact CC2 at the height position of the word line WL.

As illustrated in FIGS. 13A and 13B, a plurality of contacts CC2 are disposed in the contact region ER2 of the semiconductor memory device 2 according to the modification example. The contact CC2 includes: an extension portion CC2t that extends in the stacked body LM; and the expansion portion CC2p that spreads in the word line WL or the select gate lines SGD and SGS to be connected.

On an end surface of the expansion portion CC2p, at least the metal element-containing layer 58 among the metal element-containing layers 28 and 58 is not disposed. Alternatively, on an end surface of the expansion portion CC2p, both of the metal element-containing layers 28 and 58 do not need to be disposed. Alternatively, the expansion portion CC2p is connected to the word line WL or the like with the metal element-containing layer 28 interposed therebetween without at least the metal element-containing layer 58 interposed therebetween, or directly without both of the metal element-containing layers 28 and 58 interposed therebetween.

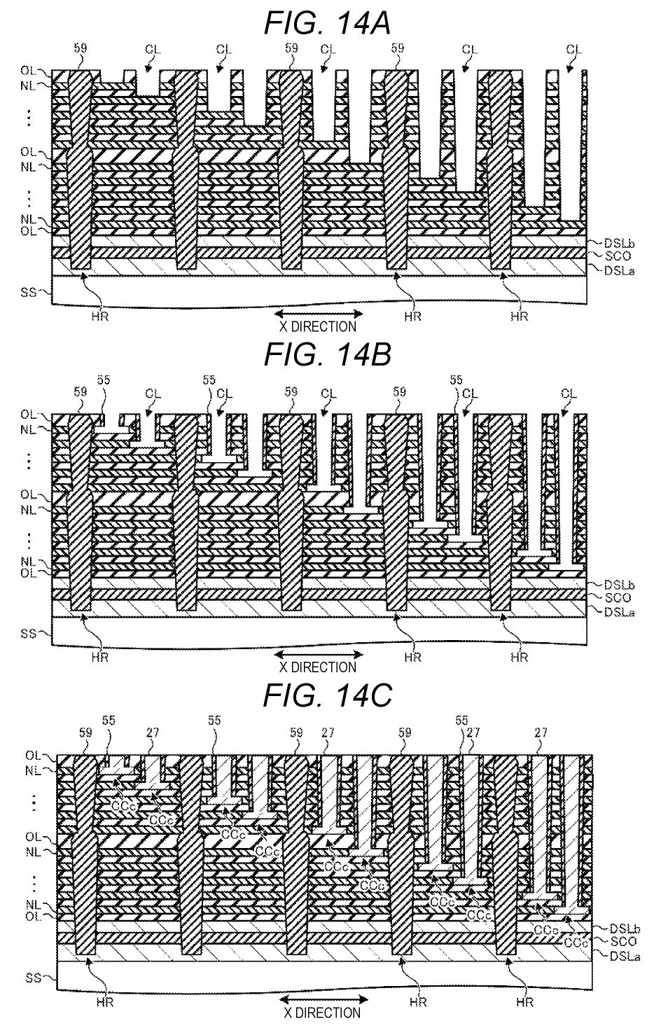

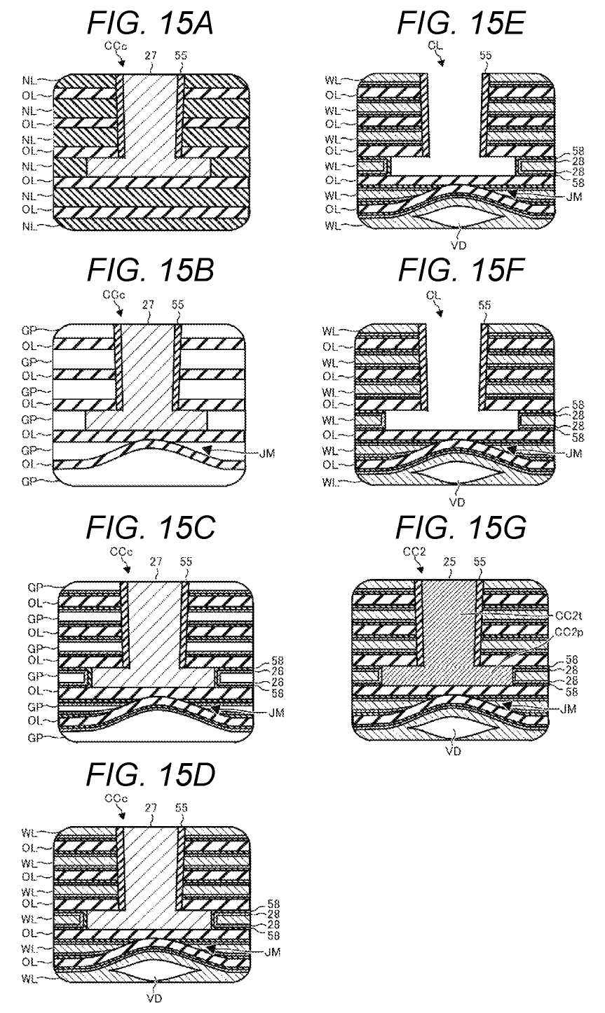

FIGS. 14A to 15G are cross-sectional views sequentially illustrating a part of a procedure of a method of forming the contact CC2 according to the modification example of the embodiment.

FIGS. 14A to 14C are cross-sectional views taken along the X direction illustrating a region that subsequently forms the contact region ER2.

As illustrated in FIG. 14A, even in the semiconductor memory device 2 according to the modification example, a plurality of contact holes CL that reach insulating layers NL at different depths are formed in the region that subsequently forms the contact region ER2.

As illustrated in FIG. 14B, a side wall of each of the contact holes CL is covered with the insulating layer 55. In addition, by allowing a removal solution for the insulating layer NL such as hot phosphoric acid to flow into each of the contact holes CL, the insulating layer NL exposed to the bottom surface of the contact hole CL is retracted by a predetermined distance.

As illustrated in FIG. 14C, each of the contact holes CL is filled with a sacrificial layer 27 such as an amorphous silicon layer. As a result, in the region that subsequently forms the contact region ER2, a contact CCc where the plurality of contact holes CL are filled with the sacrificial layer 27 is formed.

Next, as illustrated in FIGS. 15A to 15G, the replacement process of the word lines WL and the like is performed. FIGS. 15A to 15G are enlarged cross-sectional views illustrating the contact CCc at the height position of the insulating layer NL or the word line WL.

As illustrated in FIG. 15A, through the process of FIG. 14C, the contact CCc that extends up to a predetermined depth in the insulating layers NL and OL and reaches a predetermined insulating layer NL is formed.

As illustrated in FIG. 15B, the insulating layer NL is removed, and the stacked body including the plurality of gap layers GP and having a weak structure is formed. As a result, in a region below each of the contacts CCc, the remaining insulating layer OL is bent, and any of the gap layers GP above and below the insulating layer OL may include the blocked portion JM. In the example of FIG. 15B, the gap layer GP above the bent insulating layer OL includes the blocked portion JM, and the gap layer GP below the bent insulating layer OL is spread in the stacking direction.

As illustrated in FIG. 15C, the metal element-containing layers 58 and 28 are formed in this order on both surfaces of the gap layer GP in the vertical direction and on an end surface of the sacrificial layer 27 that spreads in the gap layer GP of the contact CCc.

As illustrated in FIG. 15D, the gap layer GP covered with the metal element-containing layers 58 and 28 is filled with a conductive material such as tungsten to form the plurality of word lines WL and the like. At this time, in the example of FIG. 15D, the word line WL above the bent insulating layer OL includes the blocked portion JM, and the word line WL below the bent insulating layer OL includes the void VD.

Meanwhile, even in the contact CCc including the bent insulating layer OL below the contact CCc, in the gap layer GP that the contact CCc reaches, the influence of the bending of the insulating layer OL is reduced by the flat sacrificial layer 27 spread in the gap layer GP. Therefore, formation failure of the word line WL or the like is also prevented.

As illustrated in FIG. 15E, the sacrificial layer 27 filled in the contact CCc is removed, and the contact hole CL is formed again.

As illustrated in FIG. 15F, at least the metal element-containing layer 58 exposed to the end surface of the expansion portion of the lower end portion of the contact CCc is removed to expose the metal element-containing layer 28. Alternatively, both of the metal element-containing layers 58 and 28 may be removed to expose the word line WL.

As illustrated in FIG. 15F, the contact hole CL is filled with the conductive layer 25. As a result, the contact CC2 according to the modification example including the extension portion CC2t and the expansion portion CCp is formed.

In the semiconductor memory device 2 according to the modification example, at least the metal element-containing layer 58 is not disposed on the end surface of the expansion portion CCp of the contact CC2. As a result, the expansion portion CCp is in contact with the word line WL with the conductive metal element-containing layer 28 interposed therebetween or directly, and electrical connection between the contact CC2 and the word line WL can be more reliably ensured.

The method of manufacturing the semiconductor memory device 2 according to the modification example includes filling the contact hole CL with the sacrificial layer 27, in which the contact CC2 is formed after the formation of the stacked body LM through the replacement process.

This way, the replacement process is performed after filling the contact hole CL including the expansion portion with the sacrificial layer 27. Even with the method, during the replacement process, the blocking of the word line WL in the lower end portion of the contact CCc can be prevented.

In addition, when the sacrificial layer 27 is removed after the replacement process, by removing at least the metal element-containing layer 58 on the end surface of the expansion portion, electrical connection between the contact CC2 and the word line WL can be improved.

With the semiconductor memory device 2 according to the modification example and the method of manufacturing the same, the same effects as those of the semiconductor memory device 1 according to the above-described embodiment and the method of manufacturing the same are obtained.

### Other Modification Examples

In the embodiment and the modification example described above, in the method of leading out the plurality of word lines WL and the like on one side, contacts CC are disposed for every two block regions BLK in the contact regions ER and ER2 on one side in the X direction. However, in the method of leading out the word lines WL and the like on one side, a layout where the contacts are disposed on one side in the X direction in the same block region BLK may be adopted, and the disposition order is not limited thereto.

In addition, in the embodiment and the modification example described above, the contact regions ER and ER2 are provided in both of the end portions of the stacked body LM in the X direction. However, the present disclosure is not limited to this example. The contact region may be provided, for example, in the central portion of the stacked body LM.

In addition, in the embodiment and the modification example described above, the stacked body LM having the 2 tier structure is provided. However, the configuration of the stacked body may have a 1 tier structure or may have a 3 or higher tier structure.

In addition, in the embodiment and the modification example described above, the pillar PL is connected to the source line SL on the side surface of the channel layer CN, but the present disclosure is not limited thereto. For example, the memory layer on the bottom surface of the pillar may be removed such that the pillar is connected to the source line in the lower end portion of the channel layer.

In addition, in the embodiment and the modification example described above, the peripheral circuit CBA is disposed above the stacked body LM. However, the peripheral circuit may be disposed below the stacked body or in the same layer as the stacked body.

When the peripheral circuit is disposed below the stacked body, for example, the source line and the stacked body may be formed on the insulating layer of the semiconductor substrate including the peripheral circuit covered with the insulating layer. When the peripheral circuit is disposed in the same layer as the stacked body, the stacked body may be formed at a position different from the position of the peripheral circuit on the semiconductor substrate on which the peripheral circuit is formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of first conductive layers and a plurality of insulating layers alternately stacked on top of one another in a vertical direction;
a contact extending through the stacked body and reaching one of the plurality of first conductive layers; and
a first pillar including a semiconductor layer that is separated from the contact and extends through the stacked body in the vertical direction,
wherein the contact includes:
an extension portion extending through the stacked body in the vertical direction; and
an expansion portion extending from a lower end portion of the extension portion to the one first conductive layer to contact the one first conductive layer.

2. The semiconductor memory device according to claim 1, further comprising a first metal element-containing layer interposed between the one first conductive layer and an end surface of the expansion portion facing the one first conductive layer.

3. The semiconductor memory device according to claim 2, further comprising a second metal element-containing layer interposed between the one first conductive layer and the end surface of the expansion portion and on the expansion portion side with respect to the first metal element-containing layer.

4. The semiconductor memory device according to claim 1, further comprising a plurality of second pillars extending through the stacked body in the vertical direction in a disposition region of the contact,
wherein the plurality of second pillars surround the contact when seen from the vertical direction.

5. The semiconductor memory device according to claim 1,
wherein at least another one of the first conductive layers below the one first conductive layer in a region surrounded by a plurality of second pillars includes a blocked portion or a void.

6. A semiconductor memory device comprising:
a stacked body including a plurality of first conductive layers and a plurality of insulating layers alternately stacked on top of one another in a vertical direction;
a contact extending through the stacked body in the vertical direction and reaching one of the plurality of first conductive layers; and
a first pillar including a semiconductor layer that is separated from the contact and extends through the stacked body in the vertical direction,
wherein the contact includes:
an extension portion extending through the stacked body in the vertical direction; and
an expansion portion extending from a lower end portion of the extension portion to the one first conductive layer to be connected to the one first conductive layer; and
at least another one of first conductive layers below the one first conductive layer includes a blocked portion or a void at a position overlapping the contact, when seen from the vertical direction.

7. A method of manufacturing a semiconductor memory device, comprising:
forming a first stacked body including a plurality of first sacrificial layers and a plurality of insulating layers alternately stacked on top of one another in a vertical direction;
forming a contact hole that extends through the first stacked body in the vertical direction and reaches one of the plurality of first sacrificial layers;
forming a pillar including a semiconductor layer that is separated from the contact hole and extends through the first stacked body in the vertical direction; and
replacing the plurality of first sacrificial layers with a plurality of first conductive layers to form a second stacked body where the plurality of first conductive layers and the plurality of insulating layers are alternately stacked on top of one another in the vertical direction,
wherein the formation of the contact hole includes:
forming an expansion portion in a lower end portion of the contact hole by allowing the contact hole to reach the one first sacrificial layer and subsequently retracting the one first sacrificial layer from the lower end portion by a predetermined distance by wet etching.

8. The method of manufacturing a semiconductor memory device according to claim 7, further comprising filling the contact hole including the expansion portion with a second conductive layer to form a contact.

9. The method of manufacturing a semiconductor memory device according to claim 8,
wherein the contact is formed before the formation of the second stacked body.

10. The method of manufacturing a semiconductor memory device according to claim 8,
wherein the formation of the contact hole further includes
filling the contact hole including the expansion portion with a second sacrificial layer, and
the contact is formed after the formation of the second stacked body.
